(19) United States
(12) Patent Application Publication
(10) Pub. No.: US 2023/0359122 A1
(43) Pub. Date: Nov. 9, 2023

(54) PHOTOSENSITIVE RESIN COMPOSITION, METHOD FOR PRODUCING PATTERNED CURED FILM, CURED FILM, INTERLAYER INSULATING FILM, COVER COAT LAYER, SURFACE PROTECTION FILM, AND ELECTRONIC COMPONENT

(71) Applicant: HD Microsystems, Ltd., Tokyo (JP)

(72) Inventors: Atsutaro YOSHIZAWA, Ibaraki (JP); Akira ASADA, Ibaraki (JP)

(21) Appl. No.: 17/919,664

(22) PCT Filed: Apr. 19, 2021
(86) PCT No.: PCT/JP2021/015790

§ 371 Date: Oct. 18, 2022

(30) Foreign Application Priority Data
Apr. 20, 2020 (JP) 2020-074913

(51) Int. Cl. G03F 7/20; G03F 7/028; G03F 7/037; G03F 7/00

(52) U.S. Cl. CPC G03F 7/037; G03F 7/0035; G03F 7/028; G03F 7/2002

(57) ABSTRACT

A photosensitive resin composition comprising (A) a polyimide precursor having a polymerizable unsaturated bond; (B) a polymerizable monomer having an alicyclic skeleton; (C) a photopolymerization initiator; and (D) one or more compounds selected from the group consisting of tetrazole and a tetrazole derivative.

### TECHNICAL FIELD

The invention relates to a photosensitive resin composition, a method for producing a pattemed cured film, a cured film, an interlayer insulating film, a cover coating layer, a surface protective film, and an electronic component.

### BACKGROUND ART

Hitherto, polyimides and polybenzoxazoles having excellent heat resistance, electrical characteristics, mechanical characteristics, and the lice at the same time have been used for the surface protective film and the interlayer insulating film in semiconductor elements. In recent years, photosensitive resin compositions in which photosensitive characteristics are imparted to their resins themselves are used. By using such photosensitive resin compositions, the producing process of a pattemed cured film can be simplified, and a complicated producing process can be shortened (for example, refer to Patent Document 1).

In recent years, the miniaturization of transistors which has supported the enhancement of the performance of computers has come a limit of scaling law, and a laminated device structure in which semiconductor elements are three-dimensionally laminated for further enhancement of the performance and speeding up has attracted attention (for example, refer to Non-Patent Document 1). Among the laminated device structures, the Multi-die Fanout Wafer Level Packaging is a package that collectively seals a plurality of dies in one package, and has attracted attention because it can be expected to have lower costs and higher performance than conventionally proposed fan-out wafer level packages (manufactured by sealing one die in one package).

In producing a multi-die fan-out wafer level package, low-temperature curing is strongly required from the viewpoint of protecting a high-performance die, protecting a sealing material having low heat resistance, and increasing yield (for example, see Patent Document 2).

### RELATED ART DOCUMENTS

### Patent Documents

[Patent Document 1] JP 2009-265520 A
[Patent Document 2] WO 2008/111470A1

### Non-Patent Document

[Non-Patent Document 1] “Semiconductor Technical Yearbook 2013, Part: Packaging/Mounting”, Nikkei Business Publications, Inc., December 2012, p. 41-50

### SUMMARY OF THE INVENTION

When a cured film is used for a redistribution layer, for example, high adhesiveness is required in addition to high resolution in order to be suffered from fine patterning. However, a cured film having sufficient adhesiveness could not be obtained from a conventional resin composition.

An object of the invention is to provide a photosensitive resin composition capable of forming a cured film which maintains high adhesiveness after storage at a high temperature condition even when cured at a temperature of 200° C. or lower, a method for producing a pattemed cured film using the same, a cured film, an interlayer insulating film, a cover coating layer, a surface protective film, and an electronic component.

As a result of intensive studies in view of the above problems, the inventors have found that by combining one or more compounds selected from the group consisting of tetrazole and a tetrazole derivative with a specific polyimide precursor, a polymerizable monomer having an alicyclic skeleton, and a photopolymerization initiator, a cured film capable of maintaining adhesiveness after storage at a high temperature condition even when cured at a temperature of 200° C. or lower, can be obtained, and thus the invention has been completed.

According to the invention, the following photosensitive resin composition and so on are provided.

1. A photosensitive resin composition comprising:
(A) a polyimide precursor having a polymerizable unsaturated bond;
(B) a polymerizable monomer having an alicyclic skeleton;
(C) a photopolymerization initiator; and
(D) one or more compounds selected from the group consisting of tetrazole and a tetrazole derivative.

2. The photosensitive resin composition according to 1, wherein the component (A) is a polyimide precursor having a structural unit represented by the following formula (1):

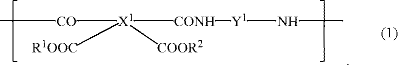

wherein in the formula (1), X¹ is a tetravalent aromatic group; Y¹ is a divalent aromatic group; R¹ and R² are independently a hydrogen atom, a group represented by the folowing formula (2), or an aliphatic hydrocarbon group including 1 to 4 carbon atoms; at least one of R¹ and R² is a group represented by the following formula (2); a -COOR¹ group and a —CO— group are on the ortho-position to each other, and a -COOR² group and a —CONH— group are on the ortho-position to each other.

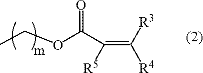

wherein in the formula (2), R³ to R⁵ are independently a hydrogen atom or an aliphatic hydrocarbon group induding 1 to 3 carbon atoms; and m is an integer of 1 to 10.

3. The photosensitive resin composition according to claim 1 or2, wherein the component (D) comprises one or more selected from the group consisting of compounds represented by each of the following formulas (11) to (13):

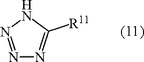

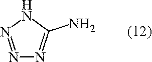

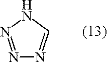

wherein in the formula (11), R¹¹ is an aliphatic hydrocarbon group including 1 to 4 carbon atoms.

4. The photosensitive resin composition according to claim 3, wherein the component (D) comprises two or more selected from the group consisting of the compounds represented by each of the formulas (11) to (13).

5. The photosensitive resin composition according to claim 3 or 4, wherein the component (D) comprises the compound represented by the formula (11), and further comprises one or more selected from the group consisting of the compounds represented by each of the formulas (12) and (13).

6. The photosensitive resin composition according to any one of 1 to 5, further comprising (F) a thermal polymerization initiator.

7. A method for producing a pattemed cured film, comprising: a step of forming a photosensitive resin film by applying the photosensitive resin composition according to any one of 1 to 6 on a substrate, followed by drying;
a step of subjecting the photosensitive resin film to pattem-exposure to obtain a resin film;
a step of developing the resin film having undergone the pattern exposure using an organic solvent to obtain a pattemed resin film; and
a step of heat-treating the pattemed resin film.

8. The method for producing a pattemed cured film according to 7, wherein the heat treatment is carried out at a temperature of 200° C. or lower.

9. A cured film obtained by curing the photosensitive resin composition according to any one of 1 to 6.

10. The cured film according to 9, which is a pattemed cured film.

11. An interlayer insulating film, a cover coating layer, or a surface protective film manufactured by using the cured film according to 9 or 10.

12. An electronic component comprising the interlayer insulating film, the cover coating layer, or the surface protective film according to 11.

According to the invention, it is possible to provide a photosensitive resin composition capable of forming a cured film which can maintain high adhesiveness after storage at a high temperature condition, even when cured at a temperature of 200° C. or lower, a method for producing a pattemed cured film using the same, a cured film, an interlayer insulating film, a cover coating layer, a surface protective film, and an electronic component.

### BRIEF DESCRIPTION OF THE DRAWINGS

FIG. 1 is a schematic diagram of the method for producing an electronic component according to one embodiment of the invention.

### MODE FOR CARRYING OUT THE INVENTION

Hereinafter, embodiments of the photosensitive resin composition, a method for producing a pattemed cured film, a cured film, an interlayer insulating film, a cover coating layer, a surface protective film, and an electronic component of the invention will be described in detail. The invention is not limited to the following embodiments.

In the specification, “A or B” means that either of A and B may be included, or both of A and B may be included. Moreover, the term “step” herein includes not only a step independent from other steps but also a step although it cannot be clearly distinguished from the other steps, but it can achieve the expected action. A numerical value range represented by using “to” indicates a range induding numerical values described before and after “10” as the minimum value and the maximum value, respectively. Moreover, when a plurality of materials corresponding to each component exist in a composition, unless otherwise specified, the content of each component in the composition herein means the total amount of the plurality of materials existing in the composition. Further, unless otherwise specified, materials listed as examples may be used alone or in combination of two or more.

The term “(meth)acrylic group” herein means an “acrylic group” and a “methacrylic group”.

### Photosensitive Resin Composition

The photosensitive resin composition of the invention contains (A) a polyimide precursor having a polymerizable unsaturated bond (hereinafter, also referred to as “component (A)”); (B) a polymerizable monomer having an alicyclic skeleton (hereinafter, also referred to as “component (B)”); (C) a photopolymerization initiator (hereinafter, also referred to as “component (C)”); and (D) one or more compounds selected from the group consisting of tetrazole and a tetrazole derivative (hereinafter, also referred to as “component (D)”). The photosensitive resin composition of the invention is preferably a negative photosensitive resin composition.

The photosensitive resin composition of the invention exhibits excellent photosensitive characteristics due to containing the above-described components. In addition, even when cured at 200° C. or lower, a cured film exhibiting adhesiveness, particularly adhesiveness to copper, equivalent to that of a cured film obtained by high-temperature curing can be formed. In addition, it is possible to form a cured film having high adhesiveness and little change in appearance, even after a durability test under high temperature and high humidity conditions and a high temperature exposure test in air.

Hereinafter, each component will be described.

### (Component (A): Polyimide Precursor Having Polymerizable Unsaturated Bond)

The component (A) is not particularly limited as long as it is a polyimide precursor having a polymerizable unsaturated bond, and a polyimide precursor having high transmittance when i-ray is used as a light source at the time of pattern exposure and exhibiting high cured film characteristics even at low-temperature curing of 200° C. or lower is preferable.

Examples of the polymerizable unsaturated bond indude a double bond between carbon atoms and the like.

The component (A) is preferably a polyimide precursor having a structural unit represented by the following formula (1). Thus, a cured film having a high transmittance of the i-ray and good curability even when curing at a low temperature of 200° C. or lower, can be formed.

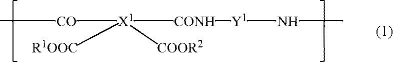

wherein in the formula (1), X¹ is a tetravalent aromatic group; Y¹ is a divalent aromatic group; R¹ and R² are independently a hydrogen atom, a group represented by the following formula (2), or an aliphatic hydrocarbon group including 1 to 4 carbon atoms; at least one of R¹ and R² is the group represented by the following formula (2); a -COOR¹ group and a —CO— group are on the ortho-position to each other, and a -COOR² group and a —CONH— group are on the ortho-position to each other,

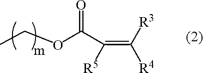

Wherein in the formula (2), R³ to R⁵ are independently a hydrogen atom or an aliphatic hydrocarbon group induding 1 to 3 carbon atoms; and m is an integer of 1 to 10 (preferably an integer of 2 to 5, and more preferably 2 or 3).

The tetravalent aromatic group for X¹ may be a tetravalent group containing an aromatic hydrocarbon structure (for example, induding 6 to 20 carbon atoms) or a tetravalent group containing an aromatic heterocyclic structure (for example, induding 5 to 20 atoms). X¹ is preferably a tetravalent group containing an aromatic hydrocarbon structure.

Examples of the tetravalent group containing an aromatic hydrocarbon group for X¹ include, but are not limited to, the groups shown below.

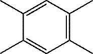

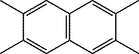

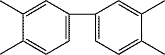

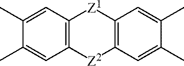

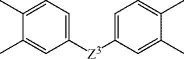

wherein in the formula, Z¹ and Z² are independently a divalent group which does not conjugated to both the benzene rings to be bonded thereto, or a single bond; Z³ is an ether bond (—O—) or a sulfide bond (—S—).

The divalent group for Z¹ and Z² is preferably —O—, —S—, a methylene group, a bis(trifluoromethyl)methylene group, or a difluoromethylene group, and more preferably —O—.

Z³ is preferably —O—.

The divalent aromatic group for Y¹ may be a divalent aromatic hydrocarbon group (for example, including 6 to 20 carbon atoms) or a divalent aromatic heterocyclic group (for example, including 5 to 20 atoms). Y¹ is preferably a divalent aromatic hydrocarbon group.

Examples of the divalent aromatic hydrocarbon group for Y¹ include, but are not limited to, a group represented by the following formula (21):

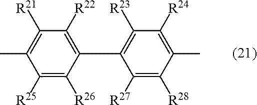

wherein in the formula (21), R²¹ to R²⁸ are independently a hydrogen atom, a monovalent aliphatic hydrocarbon group, or a monovalent organic group having a halogen atom.

The monovalent aliphatic hydrocarbon group for R²¹ to R²⁸ (preferably including 1 to 10 carbon atoms, more preferably including 1 to 6 carbon atoms) is preferably a methyl group.

The monovalent organic group having a halogen atom (preferably fluorine atom) for R²¹ to R²⁸ is preferably a monovalent aliphatic hydrocarbon group having a halogen atom (preferably induding 1 to 10 carbon atoms, more preferably including 1 to 6 carbon atoms), and more preferably a trifluoromethyl group.

In the formula (21), for example, R²² and R²³ may be monovalent aliphatic hydrocarbon groups (e.g., methyl groups), and R²¹ and R²⁴ to R²⁸ may be hydrogen atoms.

Examples of the aliphatic hydrocarbon group including 1 to 4 (preferably 1 or 2) carbon atoms for R¹ and R² in the formula (1) indude a methyl group, an ethyl group, an n-propyl group, a 2-propyl group, an n-butyl group, and the like.

In the formula (1), at least one of R¹ and R² is the monovalent group represented by the formula (2), and preferably both R¹ and R² are the groups represented by the formula (2).

Examples of the aliphatic hydrocarbon group induding 1 to 3 (preferably 1 or 2) for R³ to R⁵ in the formula (2) indude a methyl group, an ethyl group, an n-propyl group, a 2-propyl group, and the like. A methyl group is preferable.

The polyimide precursor having the structural unit represented by the formula (1) can be produced by, for example, reacting a tetracarboxylic dianhydride represented by the following formula (22) with a diamino compound represented by the following formula (23) in an organic solvent such as N-methyl-2-pyrrolidone (hereinafter referred to as “NMP”) to produce a polyamic acid, adding a compound represented by the following formula (24) to the polyamic acid, and reacting them in an organic solvent to introduce an ester group in whole or in part.

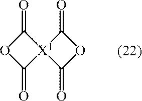

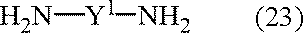

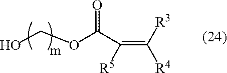

wherein in the formula (22), X¹ is as defined in the formula (1); in the formula (23), Y¹ is as defined in the formula (1); and in the formula (24), R³ to R⁵ and m are as defined in the formula (2).

The tetracarboxylic dianhydride represented by the formula (22) and the diamino compound represented by the formula (23) may be used alone or in combination of two or more, respectively.

The content of the structural unit represented by the formula (1) is preferably 50 mol% or more, more preferably 80 mol% or more, and still more preferably 90 mol% or more, based on all the structural units of the component (A). The upper limit is not particularly limited, and may be 100 mol%.

The component (A) may have a structural unit other than the structural unit represented by the formula (1). Examples of the structural unit other than the structural unit represented by the formula (1) indude a structural unit represented by the following formula (31):

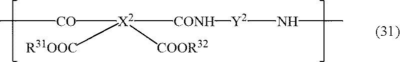

wherein in the formula (31), X² is a tetravalent aromatic group; Y² is a divalent aromatic group; R³¹ and R³² are independently a hydrogen atom or aliphatic hydrocarbon group induding 1 to 4 carbon atoms; a -COOR³² group and a —CONH— group are on the ortho-position to each other, and a -COOR³¹ group and a —CO— group are on the ortho-position to each other.

Examples of the tetravalent aromatic group for X² in the formula (31) indude the same groups as the tetravalent aromatic group for X¹ in the formula (1). Examples of the divalent aromatic group for Y² include the same groups as the divalent aromatic group for Y¹ in the formula (1). Examples of the aliphatic hydrocarbon group including 1 to 4 carbon atoms for R³¹ and R³² indude the same groups as the aliphatic hydrocarbon group induding 1 to 4 carbon atoms for R¹ and R² in the formula (1).

The content of the structural unit other than the structural unit represented by the formula (1) is preferably 50 mol% or less based on all the structual units of the component (A).

The structural unit other than the structural unit represented by the formula (1) may be contained in one kind or in a combination of two or more kinds.

In the component (A), the proportion of the carboxy group esterified with the group represented by the formula (2) based on the total of carboxy group and carboxy ester in the polyimide precursor is preferably 50 mol% or more, more preferably 60 to 100 mol%, and still more preferably 70 to 90 mol%.

The molecular weight of the component (A) is not particularly limited, and is preferably 10,000 to 200,000 in the number-average molecular weight.

The number-average molecular weight is determined by gel permeation chromatography (GPC) and polystyrene conversion using a standard polystyrene calibration curve. Specifically, the number-average molecular weight is determined by the method described in Examples.

### (Component (B): Polymerizable Monomer Having an Alicyclic Skeleton)

The photosensitive resin composition of the invention contains the component (B), so that hydrophobicity can be imparted to the obtained a cured film, and deterioration in adhesiveness between the cured film and a substrate under high-temperature and high-humidity conditions can be suppressed.

The number of ring carbon atoms of the alicyclic skeleton is preferably 4 to 15, and more preferably 5 to 12.

The component (B) preferably has a polymerizable unsaturated double bond-containing group, and preferably has two or three polymerizable unsaturated double bond-containing groups in order to increase the crosslinking density and photosensitivity and suppress swelling of the pattem after development.

The component (B) is preferably a compound having a (meth)acrylic group which can be polymerized with a photopolymerization initiator.

Examples of the component (B) include, but are not limited to, compounds represented by each of the following formulas (41) to (44).

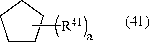

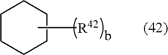

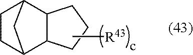

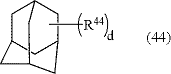

wherein in the formulas (41) to (44), R⁴¹ to R⁴⁴ are independently an aliphatic hydrocarbon group induding 1 to 4 carbon atoms or a group represented by the following formula (45);
a is an integer of 1 to 10, and at least one (preferably two or three) of R⁴¹′s is a group represented by the following formula (45);
b is an integer of 1 to 12, and at least one (preferably two or three) of R⁴²′s is a group represented by the following formula (45);
c is an integer of 1 to 16, and at least one (preferably two or three) of R⁴⁹′s is a group represented by the following formula (45);
d is an integer of 1 to 16, and at least one (preferably two) of R⁴⁰′s is a group represented by the following formula (45); and
in the formula (43), R⁴³ can be bonded to all substitution positions on the alicyclic skeleton, and in the formula (44), R⁴⁴ can be bonded to all substitution positions on the alicyclic skeleton;

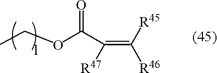

wherein in the formula (45), R⁴⁵ to R⁴⁷ are independently a hydrogen atom or an aliphatic hydrocarbon group including 1 to 3 carbon atoms, and I is an integer of 0 to 10 (preferably 0, 1 or 2).

Examples of the aliphatic hydrocarbon group induding 1 to 4 carbon atoms for R⁴¹ to R⁴⁴ in the formulas (41) to (44) indude the same groups as the aliphatic hydrocarbon group induding 1 to 4 carbon atoms for R¹ and R² in the formula (1).

Examples of the aliphatic hydrocarbon group induding 1 to 3 carbon atoms for R⁴⁵ to R⁴⁷ in the formula (45) include the same groups as the aliphatic hydrocarbon group induding 1 to 3 carbon atoms for R³ to R⁵ in the formula (2).

The content of the component (B) is preferably 1 to 50 parts by mass, more preferably 5 to 50 parts by mass, and still more preferably 5 to 30 parts by mass based on 100 parts by mass of the component (A), from the viewpoint of increasing the hydrophobicity of the cured film When the content of the component (B) is within the above range, a practical relief pattern is easily obtained, and residue after development of an unexposed portion is easily suppressed.

### (Component (C): Photopolymerization Initiator)

Examples of the component (C) preferably include, but are not imited to, benzophenone derivatives such as benzophenone, methyl o-benzoylbenzoate, 4-benzoyl-4′-methyldiphenyl ketone, dibenzyl ketone, and fluorenone; acetophenone derivatives such as 2,2′-diethoxyacetophenone, 2-hydroxy-2-methylpropiophenone, and 1-hydroxycyclohexylphenyl ketone; thioxanthone derivatives such as thioxanthone, 2-methylthioxanthone, 2-isopropylthioxanthone, and diethylthioxanthone; benzyl derivatives such as benzyl, benzyldimethyketal, and benzyl-β-methoxyethyl acetal; benzoin derivatives such as benzoin and benzoin methyl ether, and oxime esters such as 1-phenyl-1,2-butanedione-2-(O-methaxycarbonyloxime, 1-phenyl-1,2-propanedione-2-(O-methoxycarbonyl)oxime, 1-phenyl-1,2-propanedione-2-(O-ethoxycarbonyl)oxime, 1-phenyl-1,2-propanedione-2-(O-benzoyloxime, 1,3-diphenylpropanetrione-2-(O-ethoxycarbonyl)oxime, 1-phenyl-3-ethoxypropanetrione-2-(O-benzoyl)oxime, ethanone, 1-[9-ethyl-6-(2-methylbenzoyl)-9H-carbazol-3-y] 1-(O-acetyloxime), a compound represented by the following formula. Oxime esters are preferable from the viewpoint of photosensitivity.

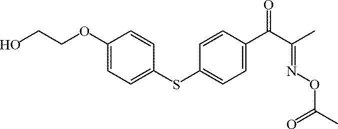 [SMILES: CC(=O)O/N=C(\C)C(=O)c1ccc(Sc2ccc(OCCO)cc2)cc1]

The content of the component (C) is preferably from 0.1 to 20 parts by mass, more preferably from 0.1 to 10 parts by mass, and still more preferably from 0.1 to 8 parts by mass, based on 100 parts by mass of the component (A). When the content of the component (C) is within the above range, the crosslink tends to be uniform in the film thickness direction, and a practical relief pattern can be easily obtained.

(Component (D): One or more compounds selected from the group consisting of tetrazole and tetrazole derivative)

The photosensitive resin composition of the invention can form a cured product having excellent adhesiveness even after storage at a high-temperature condition with the addition of the component (D). In addition, by using the component (B) and the component (D) in combination, it is possible to further increase the adhesiveness even when curing at a low-temperature of 200° C. or lower, and to suppress the change in appearance of the cured film.

Examples of the component (D) indude compounds represented by each of the following formulas (11) to (13).

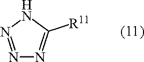

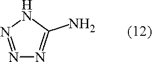

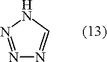

wherein in the formula (11), R¹¹ is an aliphatic hydrocarbon group including 1 to 4 carbon atoms.

Examples of the aliphatic hydrocarbon group including 1 to 4 carbon atoms for R¹¹ in the formula (11) indude the same groups as the aliphatic hydrocarbon group including 1 to 4 carbon atoms for R¹ and R² in the formula (1).

The component (D) may be used alone or in combination of two or more. For example, two or more compounds selected from the group consisting of the compounds represented by each of the formulas (11) to (13) may be used.

The component (D) preferably contains the compound represented by the formula (11), and more preferably contains, in addition to the compound represented by the formula (11), one or more compounds selected from the group consisting of the compounds represented by each of the formulas (12) and (13). This makes it possible to further suppress the change in appearance of the cured film.

The content of the component (D) is preferably 0.01 to 50 parts by mass, and more preferably 0.1 to 20 parts by mass, based on 100 parts by mass of the component (A), and still more preferably 0.1 to 10 parts by mass, from the viewpoint of suppression of residue generation during development.

### (Component (E): Solvent)

The photosensitive resin composition of the invention generally contains (E) a solvent (hereinafter, also referred to as the “component (E)”).

Examples of the solvent indude organic solvents such as N-methylpyrrolidone, y-butyrolactone, N,N-dimethylacetamide, dimethyl sulfoxide, ethyl lactate, propyleneglycol monomethyl ether acetate, KJCMPA-100 (manufactured by KJ Chemicals Corporation; product name), and N-dimethylmorpholine.

The content of the solvent is not particularly limited, but is generally 50 to 1000 parts by mass based on 100 parts by mass of the component (A).

### (Component (F): Thermal Polymerization Initiator)

The photosensitive resin composition of the invention may further contain (F) a thermal polymerization initiator (hereinafter, also referred to as the “component (F)”).

As the component (F), a compound which does not decompose by heating (drying) for removing a solvent at the time of film formation of the photosensitive resin film, but decomposes by heating at the time of curing to generate radicals, and accelerates polymerization reaction of the components (B) with each other or between the component (A) and the component (B) is preferable. Therefore, the component (F) is preferably a compound having the decomposition point of 110° C. or higher and 200° C. or lower, and more preferably a compound having the decomposition point of 110° C. or higher and 175° C. or lower from the viewpoint of promoting the polymerization reaction at a lower temperature.

Examples of the component (F) indude bis(1-phenyl-1-methylethyl)peroxide and the like.

When the component (F) is contained, the content of the component (F) is preferably 0.5 to 20 parts by mass, based on 100 parts by mass of the component (A), more preferably 1 to 20 parts by mass in order to ensure good flux resistance, and even more preferably 1 to 10 parts by mass from the viewpoint of suppressing decrease in solubility due to decomposition during drying.

### (Other Components)

The photosensitive resin composition of the invention may contain, in addition to the above components, a coupling agent, a surfactant or a leveling agent, a polymerization inhibitor, and the like.

### (Coupling Agent)

Generally, the coupling agent reacts with the component (A) to crosslink with the component (A) in the heat treatment after development, or the coupling agent itself polymerizes in the heat treatment step. As a result, it is possible to further increase the adhesiveness between the obtained cured film and the substrate.

The coupling agent is preferably a silane coupling agent.

Examples of the preferred silane coupling agent indude a compound having an urea bond (—NH—CO—NH—). By using the coupling agent, even when curing is performed at a low temperature of 200° C. or lower, the adhesiveness to the substrate can be further enhanced.

The compound represented by the following formula (51) is more preferable from a viewpoint of excellent adhesiveness being exhibited when curing is performed at a low temperature.

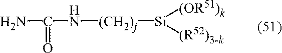

wherein in the formula (51), R⁵¹ and R⁵² are independently an alkyl group induding 1 to 5 carbon atoms; j is an integer of 1 to 10, and k is an integer of 1 to 3.

Specific examples of the compound represented by the formula (51) include ureidomethyltrimethoxysilane, ureidomethyltriethoxysilane, 2-ureidoethyltrimethoxysilane, 2-ureidoethyltriethoxysilane, 3-ureidopropyltrimethoxysilane, 3-ureidopropyltriethoxysilane, 4-ureidobutyltrimethoxysilane, 4-ureidobutyltriethoxysilane, and the like. 3-ureidopropyltriethoxysilane is preferable.

As the silane coupling agent, a silane coupling agent having a hydroxy group or a glycidyl group may be used. When such a silane coupling agent having a hydroxy group or a glycidyl group and such a silane coupling agent having a urea bond in the molecule are used in combination, the adhesiveness of the cured film to a substrate when cured at a low temperature can be further increased.

Examples of the silane coupling agent having a hydroxy group or a glycidyl group indude methylphenylsilanediol, ethylphenylsilanediol, n-propylphenylsilanediol, isopropylphenylsilanediol, n-butylphenylsilanediol, isobutylphenylsilanediol, tert-butylphenylsilanediol, diphenylsilanediol, ethylmethylphenylsilanol, n-propylmethylphenylsilanol, isopropylmethylphenylsilanol, n-butylmethylphenylsilanol, isobutylmethylphenylsilanol, tert-butylmethylphenylsilanol, ethyl(n-propyl)phenylsilanol, ethylisopropylphenylsilanol, n-butylethylphenylsilanol, isobutylethylphenyisilanol, tert-butylethylphenylsilanol, methyldiphenylsilanol, ethyldiphenylsilanol, n-propyldiphenylsilanol, isopropyldiphenylsianol, n-butyldiphenylsilanol, isobutyldiphenylsilanol, tert-butyldiphenylsilanol, phenylsilanetriol, 1,4-bis(trihydroxysilyl)benzene, 1,4-bis(methyldihydroxysilyl)benzene, 1,4-bis(ethyldihydroxysilyl)benzene, 1,4-bis(propyldihydroxysilyl)benzene, 1,4-bis(butyldihydroxysilyl)benzene, 1,4-bis(dimethylhydroxysilyl)benzene, 1,4-bis(diethylhydroxysilyl)benzene, 1,4-bis(dipropylhydroxysilyl)benzene, 1,4-bis(dibutylhydroxysily)benzene, and a compound represented by the following formula (52). Among them, the compound represented by the formula (52) is particularly preferable in order to further increase the adhesiveness to a substrate.

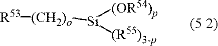

wherein in the formula (52), R⁵³ is a monovalent organic group having a hydroxy group or a glycidyl group, and R⁵⁴ and R⁵⁵ are independently an akyl group including 1 to 5 carbon atoms; o is an integer of 1 to 10, and p is an integer of 1 to 3.

Examples of the compound represented by the formula (52) indude hydroxymethyltrimethoxysilane, hydroxymethyltriethoxysilane, 2-hydroxyethyltrimethoxysilane, 2-hydroxyethyltriethoxysilane, 3-hydroxypropyltrimethoxysilane, 3-hydroxypropyltriethoxysilane, 4-hydroxybutyltrimethoxysilane, 4-hydroxybutyltriethoxysilane, glycidoxymethyltrimethoxysilane, glycidoxymethyltriethoxysilane, 2-glycidoxyethyltrimethoxysilane, 2-glycidoxyethyltriethoxysilane, 3-glycidoxypropyltrimethoxysilane, 3-glycidoxypropyltriethoxysilane, and 4-glycidoxybutyltrimethoxysilane, 4-glycidobutyltriethoxysilane, and the like.

The silane coupling agent having a hydroxy group or a glycidyl group preferably further contains a nitrogen atom, and is more preferably a silane coupling agent having an amino group or an amide bond.

Examples of the silane coupling agent having an amino group indude bis(2-hydroxymethyl)-3-aminopropyltriethoxysilane, bis(2-hydroxymethyl)-3-aminopropyltrimethoxysilane, bis(2-glycidoxymethyl)-3-aminopropyltriethoxysilane, bis(2-glycidoxymethyl)-3-aminopropyltrimethoxysilane, and the like.

Examples of the silane coupling agent having an amide bond indude a compound represented by the following formula (53).

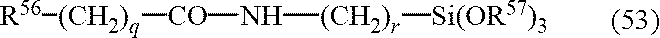

wherein in the formula (53), R⁵⁶ is a hydroxy group or a glycidyl group, q and r are independently an integer of 1 to 3, and R⁵⁷ is a methyl group, an ethyl group, or a propyl group.

When the silane coupling agent is used, the content of the silane coupling agent is preferably 0.1 to 20 parts by mass, more preferably 0.1 to 10 parts by mass, and still more preferably 0.3 to 10 parts by mass, based on 100 parts by mass of the component (A).

### (Surfactant or Leveling Agent)

With the addition of a surfactant or a leveling agent, applicability (for example, suppression of striation (unevenness in film thickness)) and developability can be increased.

Examples of the surfactant or the leveling agent include polyoxyethylene lauryl ether, polyoxyethylene stearyl ether, polyoxyethylene oleyl ether, polyoxyethylene octyl phenol ether, and the like, and examples of commercially available products indude trade names “Megafac F171,” “F173,” and “R-08” (manufactured by DIC Corporation), trade names “Fluorad FC430” and “FC431” (manufactured by 3M Japan Limited), trade names “organosiloxane polymer KP341,” “KBM303,” “KBM403,” and “KBM803” (manufactured by Shin-Etsu Chemical Co., Ltd.), and the like.

When the surfactant or the leveling agent is contained, the content of the surfactant or the leveling agent is preferably 0.01 to 10 parts by mass, more preferably 0.05 to 5 parts by mass, and still more preferably 0.05 to 3 parts by mass, based on 100 parts by mass of the component (A).

When the rust inhibitor is used, the content of the rust inhibitor is preferably 0.01 to 10 parts by mass, more preferably 0.1 to 5 parts by mass, and more preferably 0.5 to 3 parts by mass, based on 100 parts by mass of the component (A).

### (Polymerization Inhibitor)

With the addition of a polymerization inhibitor, good storage stability can be ensured.

Examples of the polymerization inhibitor indude a radical polymerization inhibitor, a radical polymerization depressant, and the like.

Examples of the polymerization inhibitor include p-methoxyphenol, diphenyl-p-benzoquinone, benzoquinone, hydroquinone, pyrogalol, phenothiazine, resorcinol, orthodinitrobenzene, paradinitrobenzene, methadinitrobenzene, phenanthraquinone, N-phenyl-2-naphthylamine, cuperone, 2,5-toluquinone, tannic acid, parabenzylaminophenol, nitrosamines, and the like.

When containing the polymerization inhibitor, the content of the polymerization inhibitor is preferably 0.01 to 30 parts by mass, more preferably 0.01 to 10 parts by mass, and still more preferably 0.05 to 5 parts by mass, based on 100 parts by mass of the component (A) from the viewpoint of storage stability of the photosensitive resin composition and heat resistance of the cured product obtained.

The photosensitive resin composition of the invention, excluding a solvent, consists essentially of components (A) to (D), and optionally a component (F), a coupling agent, a surfactant, a leveling agent, and a polymerization inhibitor, and may contain other unavoidable impurities within an amount that the effect of the invention is not impaired.

For example, 80% by mass or more, 90% by mass or more, 95% by mass or more, 98% by mass or more, 99% by mass or more, 99.5% by mass or more, 99.9% by mass or more, or 100% by mass of the photosensitive resin composition of the invention, excluding the solvent, may consist of
the components (A) to (D),
the components (A) to (D) and the component (F), or
the components (A) to (D), and optionally the component (F), a coupling agent, a surfactant, a leveling agent, and a polymerization inhibitor.

### Cured Film

The cured film of the invention can be obtained by curing the photosensitive resin composition described above. The cured film of the invention may be used as a patterned cured film or as a cured film without a pattern. The thickness of the cured film of the invention is preferably 5 to 20 µm.

### Method for Producing Patterned Cured Film

The method for producing a patterned cured film of the invention indudes a step of applying the photosensitive resin composition on a substrate, followed by drying to form a photosensitive resin film, a step of subjecting the photosensitive resin film to pattern-exposure to obtain a resin film, a step of developing the resin film undergone the pattern-exposure using an organic solvent to obtain a patterned resin film, and a step of heat-treating the patterned resin film. Thus, the patterned cured film can be obtained.

A method for producing a cured film without pattern indudes, for example, the above-described steps of forming a photosensitive resin film and of heat-treating the photosensitive resin film. Further, a step of subjecting the photosensitive resin film to exposure may be induded.

Examples of the substrate indude glass substrates, semiconductor substrates such as a Si substrate (silicon wafer), metal-oxide-insulator substrates such as a TiO₂ substrate and a SiO₂ substrate, silicon nitride substrates, copper substrates, and copper-alloy substrates.

The application method is not particularly limited, and can be performed using a spinner or the like.

The drying can be performed using a hot plate, an oven, or the like.

The drying temperature is preferably 90 to 150° C., and more preferably 90 to 120° C. in order to suppress the reaction between the component (A) and the component (D) from the viewpoint of ensuring dissolution contrast.

The drying time is preferably 30 seconds to 5 minutes.

The drying may be performed twice or more times.

A photosensitive resin film can be obtained by forming the photosensitive resin composition described above into a film shape by the method.

The thickness of the photosensitive resin film is preferably 5 to 100 µm, more preferably 8 to 50 µm, and still more preferably 10 to 30 µm.

The pattern-exposure is carried out, for example, by exposing through a photomask having a predetermined pattern.

Examples of the active lights to be irradiated include ultraviolet rays such as i-ray, visible rays, radiant rays, and the like, and i-ray is preferable.

As the exposure apparatus, a parallel exposure machine, a projection exposure machine, a stepper, a scanner exposure machine, or the like can be used.

As a result of development, a resin film having a pattern formed (patterned resin film) can be obtained. Generally, when a negative photosensitive resin composition is used, unexposed portions are removed with a developer.

As an organic solvent used as the developer, a good solvent for the photosensitive resin film can be used alone, or an appropriate combination of a good solvent and a poor solvent for the photosensitive resin film can be used.

Examples of the good solvent indude N-methylpyrrolidone, N-acetyl-2-pyrrolidone, N,N-dimethylacetamide, N,N-dimethylformamide, dimethylsulfoxide, gammabutyrolactone, α-acetyl-gammabutyrolactone, cyclopentanone, cyclohexanone, and the like.

Examples of the poor solvent include toluene, xylene, methanol, ethanol, isopropanol, propyleneglycol monomethyl ether acetate, propyleneglycol monomethyl ether, water, and the like.

Asurfactant may be added to the developer. The additive amount of the surfactant is preferably 0.01 to 10 parts by mass, and more preferably 0.1 to 5 parts by mass based on 100 parts by mass of the developer.

The development time can be, for example, two times as long as the time until the photosensitive resin film is completely dissolved from when immersed in a developer. The development time varies depending upon the component (A) used, but is preferably from 10 seconds to 15 minutes, more preferably from 10 seconds to 5 minutes, and more preferably from 20 seconds to 5 minutes from the viewpoint of productivity.

After development, washing may be performed with a rinse solution.

As the rinse solution, distilled water, methanol, ethanol, isopropanol, toluene, xylene, propyleneglycol monomethyl ether acetate, propyleneglycol monomethyl ether, or the like may be used alone or as a mix as appropriate, or may be used in a stepwise combination.

A patterned cured film can be obtained by heat-treating the patterned resin film.

The polyimide precursor of the component (A) may undergo a dehydration ring closure reaction during the heat treatment step to become a conesponding polyimide.

The temperature of the heat treatment is preferably 250° C. or lower, more preferably 120 to 250° C., and stil more preferably 200° C. or lower or 100 to 200° C.

Within the above range, damage to the substrate and the device can be kept small, the device can be produced with a high yield, and saving energy used for the process can be realized.

The time of the heat treatment is preferably 5 hours or less, more preferably 30 minutes to 3 hours. Within the above range, the crosslinking reaction or the dehydration ring closure reaction can sufficiently proceed.

The heat treatment may be canied out in atmosphere or in an inert atmosphere such as nitrogen, but from the viewpoint of preventing oxidation of the patterned resin film, the heat treatment is preferably carried out in a nitrogen atmosphere.

Examples of the device used for the heat treatment include a quartz tube oven, a hot plate, a rapid thermal annealing, a vertical diffusion furnace oven, an infrared curing oven, an electron beam curing oven, a microwave curing oven, and the like.

### Interlayer Insulating Film, Cover Coating Layer, Surface Protective Film, and Electronic Component

The cured film of the invention can be used as a passivation film, a buffer coat film, an interlayer insulating film, a cover coat layer, a surface protective film, or the like.

With the use of one or more selected from the group consisting of the passivation film, the buffer coat film, the interlayer insulating film, the cover coat layer, the surface protective film, and the like, highly reliable electronic components such as semiconductor devices, multilayer wiring boards, and various electronic devices can be produced.

An example of a producing process of a semiconductor apparatus which is an electronic component of the invention will be described with reference to the drawings.

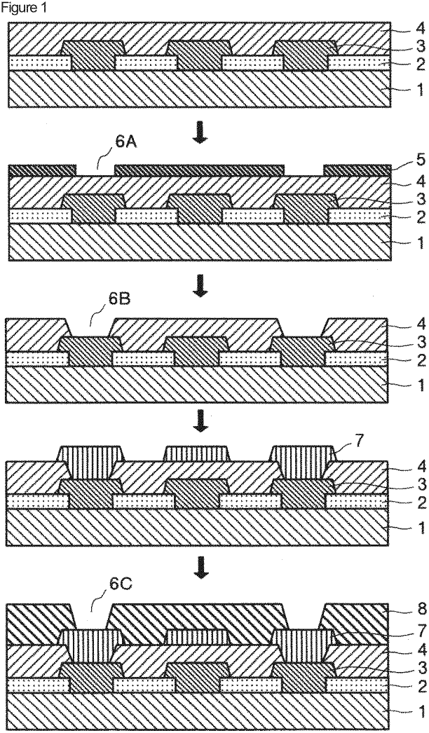

FIG. 1 is a producing process diagram of a semiconductor device having a multilayer wiring structure which is the electronic component according to an embodiment of the invention.

In FIG. 1, a semiconductor substrate 1 such as a Si substrate having a circuit device thereon is covered with a protective film 2 such as a silicon oxide film except a predetermined portion of the circuit device, and a first conductor layer 3 is formed on the circuit device exposed. Thereafter, an interlayer insulating film 4 is formed on the semiconductor substrate 1.

Next, a photosensitive resin layer 5 such as a chlorinated rubber-based resin, a phenolic novolac-based resin, or the like is formed on the interlayer insulating film 4, and a window 6A is provided by a known photolithography technique, so that a predetermined portion of the interlayer insulating film 4 is exposed.

The interlayer insulating film 4 in which the window 6A is opened is selectively etched to provide a window 6B.

Next, the photosensitive resin layer 5 is removed using an etchant that corrodes the photosensitive resin layer 5 without corroding the first conductive layer 3 exposed from the windows 6B.

Further, the second conductive layer 7 is formed by using a known photolithography technique and electrically connected to the first conductive layer 3.

In the case of forming a multilayer wiring structure of three or more layers, each layer can be formed by repeating the above steps.

Next, by using the above-mentioned photosensitive resin composition, the window 6C is opened by pattern-exposure, and a surface protective film 8 is formed. The surface protective film 8 protects the second conductive layer 7 from external stress, α rays, and the like, and the resulting semiconductor device is excellent in reliability.

In the above example, it is also possible to form an interlayer insulating film using the photosensitive resin composition of the invention.

### EXAMPLES

Hereinafter, the invention wil be described more specifically on the basis of Examples and Comparative Examples. The invention is not limited to the following Examples.

### Synthesis Example 1 (Synthesis of Polymer I)

7.07 g of 3,3′4,4′-diphenylether tetracarboxylic dianhydride (ODPA) and 4.12 g of 2,2′-dimethylbiphenyl-4,4′-diamine (DMAP) were dissolved in 30 g of N-methylpyrrolidone (NMP), stirred at 30° C. for 4 hours, and then stirred overnight at room temperature to obtain polyamide acid. To this solution, 9.45 g of trifluoroacetic anhydride was added underwater cooling, and the mixture was stirred at 45° C. for 3 hours. 7.08 g of 2-hydroxyethyl methacrylate (HEMA) was added thereto. The reaction solution was added dropwise to distilled water, the precipitates were collected by filtration, and dried under reduced pressure to obtain a polyimide precursor (hereinafter referred to as Polymer I).

The number average molecular weight was determined by standard polystyrene conversion using the gel permeation chromatography (GPC) method under the following conditions. The number-average molecular weight of Polymer I was 40,000.

Measurement was canied out for a solution of 0.5 mg of Polymer I dissolved in 1 mL of a solvent mixture [tetrahydrofuran (THF)/dimethylformamide (DMF) = 1/1 (volume ratio)].

Measuring instrument: Detector L4000UV manufactured by Hitachi, Ltd.
Pump: L6000 manufactured by Hitachi, Ltd. C-R4A Chromatopac manufactured by Shimadzu Corporation
Measuring conditions: two columns of Gelpack GL-S300MDT-5
Eluent THF/DMF = 1/1 (volume ratio) LiBr (0.03 mol/L), H₃PO₄ (0.06 mol/L)
Flow rate: 1.0 mL/min, Detector. UV 270 nm

The esterification ratio of Polymer I (the reaction ratio of the carboxylic groups of ODPA with the HEMA) was measured by NMR-measurement under the following conditions and calculated. The esterification ratio was 80% relative to the total carboxy groups, with the remaining 20% being carboxyl groups. Measurement instrument: AV400M manufactured by Bruker Japan K.K.
Magnetic field strength: 400 MHz
Reference substance: tetramethylsilane (TMS)
Solvent: dimethyl sulfoxide (DMSO)

### Examples 1 to 7 and Comparative Examples 1 to 2

### [Preparation of Photosensitive Resin Composition]

Photosensitive resin compositions of Examples 1 to 7 and Comparative Examples 1 to 2 were prepared by using components and blending amounts shown in Table 1. The blending amounts in Table 1 are indicated as parts by mass of the components (B) to (E) relative to 100 parts by mass of Polymer I.

The components used are as follows.

### Component A: Polyimide Precursor Having Polymerizable Unsaturated Bond

### Polymer I: Polymer I Obtained in Synthesis Example 1

### Component B: Polymerizable Monomer Having Alicyclic Skeleton

### B1: A-DCP (The Compound Represented by the Following Formula Manufactured by Shin-Nakamura Chemical Co., LTD., I.E. Tricyclodecanedimethanol Diacrylate)

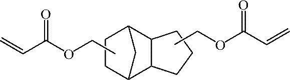

### Component B′

### B′1: A-TMMT (The Compound Represented by the Following Formula Manufactured by Shin-Nakamura Chemical Co., LTD., i.e. Pentaerythritol Tetraacrylate)

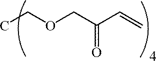

The component (B′) means a component different from the component (B) used in the invention.

### Component C: Photopolymerization Initiator

### C1: PDO (The Compound Represented by the Following Formula Manufactured by Lambson LTD., i.e. 1-Phenyl-1,2-Propanedione-2-(O-Ethaxycarbonyl)Oxime)

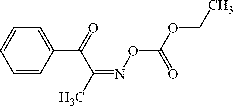 [SMILES: CCOC(=O)O/N=C(/C)C(=O)c1ccccc1]

### Component D: One or More Selected From the Group Consisting of Tetrazole and Tetrazole Derivative

### D1: 5-Methyltetrazole (The Compound Represented by the Following Formula Manufactured by Tokyo Chemical Industry Co., LTD.)

### D2: 5-Aminotetrazole (The Compound Represented by the Following Formula Manufactured by Tokyo Chemical Industry Co., LTD.)

### D3: Tetrazole (The Compound Represented by the Following Formula Manufactured by Tokyo Chemical Industry Co., LTD.)

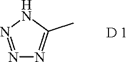

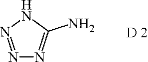

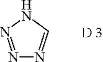

### (Component (D′))

### D′1: Benzotriazole (The Compound Represented by the Following Formula Manufactured by Tokyo Chemical Industry Co., LTD.)

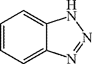

The component (D′) means a component different from the component (D) used in the invention.

### Component E: Solvent

### E1: N-Methylpyrrolidone

### E2: KJC KJCMPA-100(KJ (The Compound Represented by the Following Formula Manufactured by KJ Chemicals Corporation)

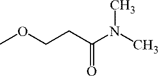

### Evaluation of Photosensitive Resin Composition

The following evaluations were performed for the obtained photosensitive resin compositions. The results are shown in Table 1.

### (Sensitivity)

The photosensitive resin composition was spin-coated on a silicon wafer using a coating device Act8 (manufactured by Tokyo Electron Limited), dried at 100° C. for 2 minutes to form a photosensitive resin film having a dry film thickness of 12 µm. The development time was set to twice the time required to completely dissolve the obtained photosensitive resin film by immersion in cyclopentanone.

A photosensitive resin film was produced in the same manner as described above, and the obtained photosensitive resin film was exposed to i-rays of 100 to 1100 mJ/cm² at 100 mJ/cm² increment through a predetermined pattern using an i-ray stepper “FPA-3000iW” (manufactured by Canon Inc.). The exposed resin film was subjected to paddle development with cyclopentanone using “Act8” (manufactured by Tokyo Electron Limited), followed by rinse cleaning with propyleneglycol monomethyl ether acetate (PGMEA) to obtain a patterned resin film.

The exposure amount required for the film residual proportion (FR) calculated by the following formula to be 80% was defined as the sensitivity. The smaller the value of the sensitivity (required exposure amount) is, the higher sensitive the material has.

FR (%)= film thickness after development/film thickness before exposure × 100

### (Resolution)

A patterned resin film was obtained by the same method as (sensitivity) except that the photomask was changed to a line-and-space photomask and the exposure amount described in Table 1 was used. The obtained patterned resin film was observed, and the smallest line width of the lines that could be patterned without peeling and residue was defined as the resolution. In Table 1, “*” indicates that a pattern could not be formed.

### (Adhesiveness)

The photosensitive resin composition was spin-coated on a Cu-plated wafer using “Act8”

(manufactured by Tokyo Electron Limited), dried at 100° C. for 2 minutes, and then dried at 110° C. for 2 minutes to form a photosensitive resin film. A ray of 500 mJ/cm² was exposed to the obtained photosensitive resin film using a proximity exposure machine (“mask aligner MAS,” manufactured by SÜSS MICROTEC SE.).

The exposed resin film was heated in a nitrogen atmosphere at 173° C. for 1 hour using a vertical diffusion furnace µ-TF (manufactured by Koyo Thermo System Co., Ltd.) to obtain a cured film (film thickness after curing: 10 µm).

The obtained cured film was placed in a saturated pressure cooker (manufactured by HIRAYAMA Manufacturing Corporation) and treated at 121° C. and 100% RH for 168 hours (PCT: Pressure Cooker Storage Test). Further, another cured film obtained by the same method as described above was held in an oven at 150° C. for 168 hours in an air-atmosphere (HTS: High Temperature Storage Test).

After the above treatment, each cured film was taken out, the epoxy resin layer at the tip of the aluminum stud was fixed to the cured film surface, and heated in an oven at 120° C. for 1 hour to adhere the epoxy resin layer and the cured film. Then, using a thin film adhesion strength measuring device Romulus (manufactured by QUAD Group Inc.), the stud was pulled vertically while increasing the load at a rate of 5 kg/min, the peeling state at the time of peeling was observed to evaluate adhesiveness in accordance with the following criteria.

◯: Cohesive fracture was occured (no peeling occured between the cured film and the Cu-plated water).
Δ: Above the peel strength of 500 kg/cm², peeling was occurred between the cured film and the Cu-plated Wafer.
X: Below the peel strength of 500 kg/cm², peeling was occurred between the cured film and the Cu-plated water.
In the case of cohesive fracture, the adhesive strength between the cured film and the Cu-plated wafer is stronger than the cohesive fracture strength of the cured film.

### (Appearance Change)

In the evaluation of (Adhesiveness), respective appearances of the cured film and the appearance of the Cu-plated wafer before and after the PCT treatment and before and after the HTS treatment were visually observed and evaluated in accordance with the following criteria.
◯: No discoloration was observed in both the cured film and Cu plating before and after the treatment.
Δ: Discoloration was observed in the Cu plating before and after the treatment.
x Discoloration was observed in both cured film and Cu plating before and after treatment.

TABLE 1

| | | | Example | | | | | | | Comp. Ex. | |
|---|---|---|---|---|---|---|---|---|---|---|---|
| | | | 1 | 2 | 3 | 4 | 5 | 6 | 7 | 1 | 2 |
| Photosensitive resin composition | Component (A) | Polymer I | 100 | 100 | 100 | 100 | 100 | 100 | 100 | 100 | 100 |
| | Component (B) | B1 | 10 | 10 | 10 | 10 | 10 | 10 | 10 | 10 | 10 |
| | Component (B′) | B′1 | 10 | 10 | 10 | 10 | 10 | 10 | 10 | 10 | 10 |
| | Component (C) | C1 | 6 | 6 | 6 | 6 | 6 | 6 | 8 | 6 | 6 |
| | Component (D) | D1 | 0.5 | 1 | 2 | 4 | 2 | 2 | 2 | | |
| | | D2 | | | | | 2 | 2 | | | |
| | | D3 | | | | | | | 2 | | |
| | Component (D′) | D′1 | | | | | | | | | 2 |
| | Component (E) | E1 | 160 | 160 | 160 | 160 | 160 | | 160 | 160 | 160 |
| | | E2 | | | | | | 160 | | | |
| Evaluation | Sensitivity (mJ/cm²) | | 400 | 400 | 400 | 400 | 400 | 400 | 400 | 400 | 400 |
| | Resolution (µm) | | 6 | 6 | 6 | 8 | 5 | 5 | 6 | 10 | 10 |
| | Adhesiveness | After PCT treatment | ◯ | ◯ | ◯ | ◯ | ◯ | ◯ | ◯ | △ | ◯ |
| | | After HTS treatment | △ | △ | ◯ | ◯ | ◯ | ◯ | ◯ | × | × |
| | Appearance change | Before and after PCT treatment | △ | △ | △ | ◯ | ◯ | ◯ | ◯ | × | △ |
| | | Before and after HTS treatment | × | × | × | △ | △ | △ | △ | × | △ |

From Table 1, it can be seen that the cured film obtained by using the photosensitive resin composition of the invention has high adhesiveness after storage at high temperature condition. In addition, the photosensitive resin composition is excellent in sensitivity and resolution, and the obtained cured film has little change in appearance.

On the other hand, it can be seen that the cured films obtained in Comparative Examples 1 and 2 without using the specific component (D) have low adhesiveness after storage at high temperature condition.

### INDUSTRIAL APPLICABILITY

The photosensitive resin composition of the invention can be used for an interlayer insulating film, a cover coat layer, a surface protective film, or the like, and the interlayer insulating film, the cover coat layer, or the surface protective film of the invention can be used for an electronic component or the like.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be induded within the scope of this invention.

The documents described in the specification and the specification of Japanese application(s) on the basis of which the present application claims Paris convention priority are incorporated herein by reference in its entirety.

1. A photosensitive resin composition comprising:
(A) a polyimide precursor having a polymerizable unsaturated bond;
(B) a polymerizable monomer having an alicyclic skeleton;
(C) a photopolymerization initiator; and
(D) one or more compounds selected from the group consisting of tetrazole and a tetrazole derivative.

2. The photosensitive resin composition according to claim 1, wherein the component (A) is a polyimide precursor having a structural unit represented by the following formula (1): 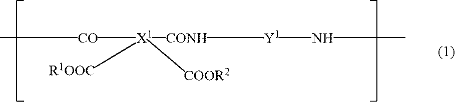
wherein in the formula (1), X¹ is a tetravalent aromatic group; Y¹ is a divalent aromatic group; R¹ and R² are independently a hydrogen atom, a group represented by the following formula (2), or an aliphatic hydrocarbon group including 1 to 4 carbon atoms; at least one of R¹ and R² is a group represented by the following formula (2); a -COOR¹ group and a —CO— group are on the ortho-position to each other; and a -COOR² group and a —CONH— group are on the ortho-position to each other: 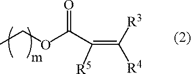
wherein in the formula (2), R³ to R⁵ are independently a hydrogen atom or an aliphatic hydrocarbon group including 1 to 3 carbon atoms; and m is an integer of 1 to 10.

3. The photosensitive resin composition according to claim 1, wherein the component (D) comprises one or more selected from the group consisting of compounds represented by each of the following formulas (11) to (13): 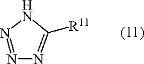 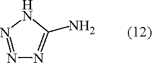 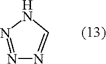
wherein in the formula (11), R¹¹ is an aliphatic hydrocarbon group including 1 to 4 carbon atoms.

4. The photosensitive resin composition according to claim 3, wherein the component (D) comprises two or more selected from the group consisting of the compounds represented by each of the formulas (11) to (13).

5. The photosensitive resin composition according to claim 3, wherein the component (D) comprises the compound represented by the formula (11), and further comprises one or more selected from the group consisting of the compounds represented by each of the formulas (12) and (13).

6. The photosensitive resin composition according to claim 1, further comprising (F) a thermal polymerization initiator.

7. A method for producing a patterned cured film, comprising:
a step of forming a photosensitive resin film by applying the photosensitive resin composition according to claim 1 on a substrate, followed by drying;
a step of subjecting the photosensitive film to pattern-exposure to obtain a resin film;
a step of developing the resin film having undergone the pattern exposure using an organic solvent to obtain a patterned resin film; and
a step of heat-treating the patterned resin film.

8. The method for producing a patterned cured film according to claim 7, wherein the heat treatment is carried out at a temperature of 200° C. or lower.

9. A cured film obtained by curing the photosensitive resin composition according to claim 1.

10. The cured film according to claim 9, which is a patterned cured film.

11. An interlayer insulating film, a cover coating layer, or a surface protective film produced by using the cured film according to claim 9.

12. An electronic component comprising the interlayer insulating film, the cover coating layer, or the surface protective film according to claim 11.
